(19) United States
(12) Patent Application Publication
(10) Pub. No.: US 2016/0005795 A1
(43) Pub. Date: Jan. 7, 2016

(54) ORGANIC TANDEM PHOTOVOLTAIC DEVICE AND METHODS

(71) Applicant: THE REGENTS OF THE UNIVERSITY OF CALIFORNIA, Oakland, CA (US)

(72) Inventors: Yang Yang, Los Angeles, CA (US); Rui Zhu, Los Angeles, CA (US); Chun Chao Chen, Temple City, CA (US); Gang Li, Arcadia, CA (US)

(21) Appl. No.: 14/777,452

(22) PCT Filed: Mar. 14, 2014
(86) PCT No.: PCT/US2014/028263

§ 371 Date: Sep. 15, 2015

Related U.S. Application Data
(60) Provisional application No. 61/799,156, filed on Mar. 15, 2013.

(51) Int. Cl. H01L 27/30; H01L 51/42

(52) U.S. Cl. CPC H01L 27/302; H01L 51/4253; H01L 2251/303; H01L 2251/308

(57) ABSTRACT

An organic tandem photovoltaic device includes a first electrode, a second electrode spaced apart from said first electrode, first and second photoactive organic bulk heterojunction layers, and an interconnecting layer. The interconnecting layer is between and electrically connects the first and second photoactive organic bulk heterojunction layers. The interconnecting layer includes an electron extracting interface layer of a first inorganic material and a hole extracting interface layer of a second inorganic material.

### CROSS-REFERENCE TO RELATED APPLICATION

This application claims priority to U.S. Provisional Application No. 61/799,156 filed Mar. 15, 2013, the entire contents of which are hereby incorporated by reference.

### STATEMENT OF GOVERNMENT SUPPORT

This invention was made with U.S. Government support under Grant No. FA9550-12-1-0074, awarded by the U.S. Air Force, Office of Scientific Research. The Government has certain rights in this invention.

### TECHNICAL FIELD

The field of the currently claimed embodiments of this invention relates to photovoltaic devices and methods of manufacturing the same, and more particularly devices and methods directed to organic tandem photovoltaic devices with interconnecting layers.

### BACKGROUND

Solar cell technology has been expected to be the most effective method in producing clean energy at low cost and minimum pollution. Beginning from last century, solar cell technologies have evolved based on various materials systems used for harvesting solar energy. The most traditional and most commonly available kind of solar cell technology is based on crystalline silicon as the active absorbing material. However, due to the high cost of purifying silicon into a high crystalline state, the application of silicon-based solar cells as a major energy source has been limited.

Recently, conductive and semi-conductive conjugated polymers have attracted attention for their applications in organic photovoltaics (OPVs) and organic light emitting diodes (OLEDs). OPVs have drawn intense attention due to their advantages over competing solar cell technologies. The power-conversion efficiency (PCE) of OPVs has overcome the 10% PCE barrier, implying a promising future for OPVs as a low-cost and highly efficient photovoltaic (PV) candidate for solar energy harvesting.

In the pursuit of high device efficiency, tandem structured OPVs may potentially utilize the full spectrum of solar energy and doubling the photo-voltage. In a “tandem structure,” at least two organic single solar cells are stacked on top of one and other in order to form a series connection, which results in multiplying the solar cell performance. In organic tandem solar cells, often an interconnecting layer (sometimes referred to herein as ICL) is required in connecting two adjacent photovoltaic devices. The desired functions of the interconnecting layer are to facilitate rapid charge carrier injection and provide recombination centers for injected charge carriers to recombine so the currents from two adjacent photovoltaic cells can match up equally. Most importantly, only a well-designed interconnecting layer can effectively increase the performance of organic tandem solar cells far beyond the performance of each individual solar cell.

Previously, many attempts have been made in demonstrating an organic tandem solar cell where the interconnecting layer consisted of conductive polymer and metal oxide composite, such as PEDOT:PSS and ZnO (or TiO₂). However, PEDOT:PSS is known for its acidic property and inferior air/humidity stability. The organic tandem solar cells made of PEDOT:PSS and other aqueous soluble polymer as interconnecting layers are subject to low lifetime and high material cost. Due to the absence of efficient solution processed interconnecting layers based on inorganic materials, current organic tandem solar cells may result in limited applications and questionable product lifetimes. Therefore, there exists a need for efficient organic tandem photovoltaics with increased application prospects and product lifetimes.

### SUMMARY

According to an embodiment of the current invention, an organic tandem photovoltaic device is provided. The organic tandem photovoltaic device may include a first electrode, a second electrode spaced apart from said first electrode, first and second photoactive organic bulk heterojunction layers, and an interconnecting layer. The interconnecting layer is between and electrically connects the first and second photoactive organic bulk heterojunction layers. The interconnecting layer may include an electron extracting interface layer of a first inorganic material and a hole extracting interface layer of a second inorganic material.

In another embodiment of the current invention, a method of manufacturing an organic tandem photovoltaic cell is provided. The method may include applying a first organic photovoltaic cell material via solution processing onto a substrate and applying an electron extracting interface layer via solution processing on top of the first organic photovoltaic cell material. The method may further include applying a hole extracting interface layer via solution processing on top of the electron extracting interface layer and applying a second organic photovoltaic cell material via solution processing on top of the electron extracting interface layer.

In another embodiment of the current invention, a method of manufacturing an organic, inverted tandem photovoltaic cell is provided. The method may include applying a first organic photovoltaic cell material via solution processing onto a substrate, and applying a hole extracting interface layer via solution processing on top of the first organic photovoltaic cell material. The method may further include applying an electron extracting interface layer via solution processing on top of the hole extracting interface layer, and applying a second organic photovoltaic cell material via solution processing on top of the electron extracting interface layer.

### BRIEF DESCRIPTION OF THE DRAWINGS

Further objectives and advantages will become apparent from a consideration of the description, drawings, and examples.

FIG. 1 is a schematic of an example of an organic tandem solar cell with an interconnecting layer embedded between the front and back cells according to an embodiment of the current invention.

FIGS. 2A and 2B show schematics of two device structures of organic tandem solar cells with multiple-layer interconnecting layers according to some embodiments of the current invention.

FIGS. 3A and 3B show schematics of examples of organic tandem solar cells with electron-IL and hole-IL layers according to embodiments of the current invention.

FIG. 4 shows a schematic of an example of an organic tandem solar cell showing electron-IL, hole-IL, and Recom-IL layers according to an embodiment of the current invention.

FIG. 5A shows a schematic of a photovoltaic device that has electrodes without buffer layers according to an embodiment of the current invention.

FIG. 5B shows a schematic of a photovoltaic device that has electrodes with buffer layers according to an embodiment of the current invention

FIG. 6 shows an example of an inverted tandem solar cell using metal oxide based interlayers according to an embodiment of the current invention.

FIG. 7 shows an example of an inverted tandem solar cell using metal oxide based interlayers according to an embodiment of the current invention.

FIG. 8A shows a schematic of a regular tandem device of Example 1 according to an embodiment of the current invention.

FIG. 8B shows a graph of the performance of the device in FIG. 8A.

FIG. 9A shows a schematic of a regular tandem device of Example 2 according to an embodiment of the current invention.

FIG. 9B shows a graph of the performance of the device in FIG. 8A.

FIG. 10A shows a schematic of an inverted tandem device of Example 3 according to an embodiment of the current invention.

FIG. 10B shows a graph of the performance of the device in FIG. 10A.

FIG. 11A shows a schematic of an inverted tandem device of Example 4 according to an embodiment of the current invention.

FIG. 11B shows a graph of the performance of the device in FIG. 11A.

FIG. 12A shows a schematic of an inverted tandem device of Example 5 according to an embodiment of the current invention.

FIG. 12B shows a graph of the performance of the device in FIG. 12A.

### DETAILED DESCRIPTION

Some embodiments of the current invention are discussed in detail below. In describing embodiments, specific terminology is employed for the sake of clarity. However, the invention is not intended to be limited to the specific terminology and examples selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated. All references cited in this specification are incorporated herein by reference.

As used herein, a “single junction solar cell” refers to a device having one junction of organic photoactive materials or their blends as absorbers. The organic absorbers may include polymer, oligomer, and small molecules photovoltaic materials.

As used herein, a “tandem solar cell” refers to a device structure having more than one single junction solar cell stacked in an vertical fashion.

There are several considerations in designing inorganic nanoparticles to realize the highly efficient and robust ICL for an organic tandem solar cell according to some embodiments of the invention. These considerations include: (1) effective charge transport properties for either electron or hole carriers, with the transporting ability having a weak dependence on thickness; (2) proper work function alignment with organic active layer materials and while also forming ohmic contact at the middle of tandem junction; and (3) being highly transparent to allow maximum light harvesting for the back cell. The design of an interconnecting layer with multiple interface layers (sometimes referred to herein as ILs) may be required to satisfy all of these considerations. Herein, the interface layer responsible for extracting electron carriers toward the middle of tandem solar cell is defined as the electron-IL, the interface layer responsible for extracting hole carriers as the hole-IL, and interface layer responsible for charge carriers recombination as recom-IL.

Organic tandem solar cells can use PEDOT:PSS as hole-IL and ZnO as electron-IL. The performance of a corresponding tandem solar cell can reach 10.6% efficiency under standard testing condition certified by the National Renewable Energy Laboratory (NREL). MoO₃ can be applied by thermal evaporation as the hole-IL into a tandem solar cell with ZnO as the electron-IL from the sol gel method. However, no demonstrations were previously known in the art for both solution processed electron-IL and hole-IL from inorganic nanoparticles.

In some embodiments of the current invention, vanadium oxide (V₂O₅, or VO_{X}) nanoparticles may be used as the hole-IL and ZnO nanoparticles as the electron-IL. In some embodiments, ITO nanoparticles may be used as recom-IL to form an all solution processed-based inorganic interconnecting layer for organic tandem solar cells. As a result, an organic tandem solar cell with inorganic metal and metal oxide nanoparticle interface layers may be realized that can be superior to previously known devices and can have greatly enhanced device lifetime (efficiency retention %). (See Examples 1 and 2 further below.)

Furthermore, an inorganic and hybrid ICL can be used in an inverted tandem structure according to some embodiments of the current invention. For example, MoO3 can be used for the hole-IL, PEDOT:PSS for the recom-IL, and ZnO for the electron-IL. The presence of PEDOT:PSS defines the interconnecting layer as a hybrid interconnecting layer, or hybrid ICL. An inorganic interconnecting layer, or inorganic ICL only has MoO3/ZnO. Using a hybrid ICL, performance of 10% can be achieved for an inverted tandem solar cell structure according to an embodiment of the invention. (See, e.g., Examples 3 and 4.)

Some solar cells may use a thermally deposited aluminum electrode. However, according to embodiments of the current invention, a transparent electrode made from silver nanowire composite conductor can be used instead of a thermally deposited aluminum electrode. In this way, an all solution-processed “transparent” organic tandem solar cell may be achieved according to some embodiments. (See, e.g., Example 5.)

Some aspects of embodiments of the current invention can include a novel method of preparing a metal and metal oxide nanoparticle solution and nanoparticle polymer composite solution (i.e., nanoparticle with polymer binder) to be used as electron-IL, hole-IL, and recom-IL. Further, embodiments may include a novel method of preparing a hybrid interconnecting layer using PEDOT:PSS as a high conductivity interlayer. Some embodiments may also include the design of an organic tandem solar cell in both regular and inverted tandem structure. Additionally, embodiments may include interface engineering between the organic active layer and the interconnecting layers.

According to some embodiments of the current invention, an efficient and robust interconnecting layer may be formed between two adjacent organic single junction solar cells. The interconnecting layer may connect two organic solar cells in a series connection, and the resulting tandem solar cell would have V_{OC} as the sum of two single junction cells. The design of the interconnecting layer can use air-stable and solution-processed inorganic metal and metal oxide nano-materials.

Embodiments of the current invention can be realized as various types of structures, including, for example, regular tandem structures with an inorganic interconnecting layer, and inverted tandem structures with an inorganic or hybrid interconnecting layer. Also, a regular tandem structure with an inorganic interconnecting layer may be formed with or without a recom-IL, for example. An inverted tandem structure using a hybrid interconnecting layer may be formed with PEDOT:PSS, and may be a transparent tandem structure. An inverted tandem structure may also use an inorganic interconnecting layer. Each of the above examples is discussed further below.

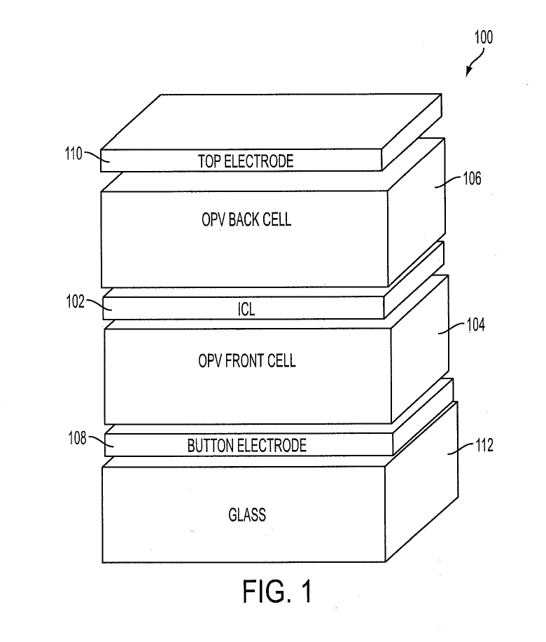

FIG. 1 shows an example of an organic tandem solar cell 100 with an interconnecting layer 102 embedded between the front cell 104 and back cell 106. The interconnecting layer 102 is a layer disposed between the photoactive layers of two single junction solar cells (i.e., front and back cells 104 and 106, respectively). Also shown in FIG. 1 is a button electrode 108 formed on a side of the front cell 104 that is opposite from the side where the interconnecting layer 102 is formed. A top electrode 110 is formed on a side of the back cell 106 that is opposite from the side where the interconnecting layer 102 is formed. A glass layer 112 is formed on an opposite side of the button electrode 108 from the front cell 104.

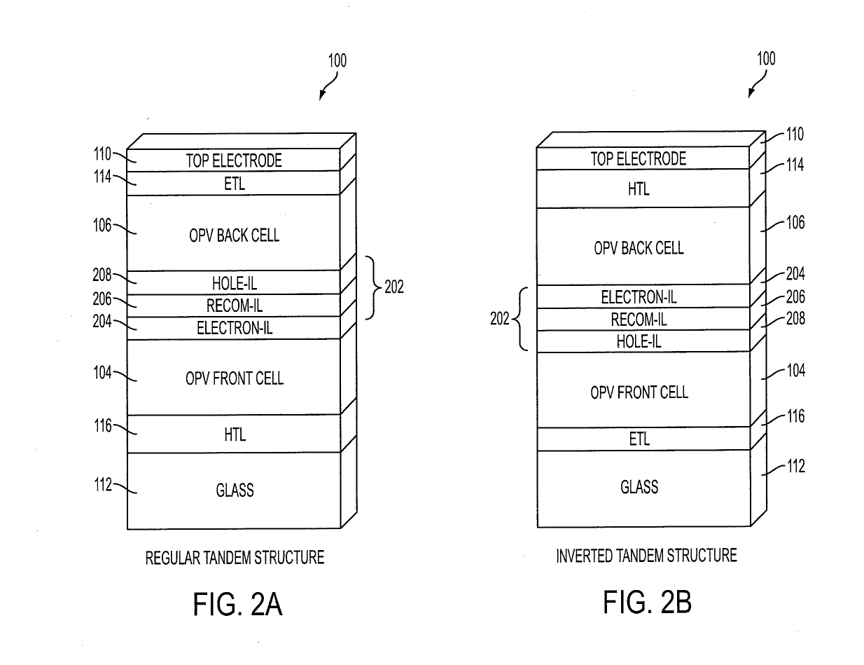

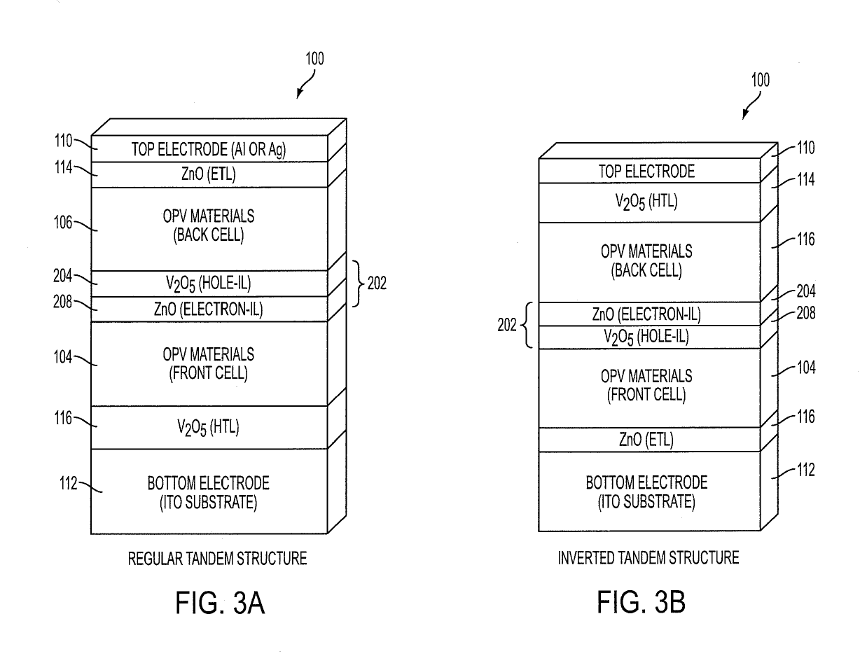

The interconnecting layer 102 can be a single or multiple layers of different inorganic materials. Each inorganic material can serve a specific function, such as a hole transporting interface layer (hole-IL), an electron transporting interface layer (electron-IL), and a recombination center IL (recom-IL). For example, FIGS. 2A and 2B show two device structures of organic tandem solar cells with multiple-layer interconnecting layers 202 having an electron-IL 204, a recom-IL 206, and a hole-IL 208. “HTL” and “ETL” denote hole and electron transporting layers, 114 and 116, respectively. The locations of the hole-IL 208 and the electron-IL 204 in the inverse tandem structure of FIG. 2B are switched relative to their positions in the regular tandem structure in FIG. 2A. Similarly, the relative locations of the HTL 116 and ETL 114 are reversed between FIGS. 2A and 2B. Examples of the hole-IL and electron-IL in the structures shown FIGS. 2A and 2B can be seen in FIGS. 3A and 3B. The recom-IL 206 (as shown in FIGS. 2A and 2B but not shown in FIGS. 3A and 3B) may be located between hole-IL 208 and electron-IL 204, however, the recom-IL is not always required to construct the tandem device. As seen in FIGS. 2A and 2B, the sequence of depositing metal and metal oxide interconnecting layer 202 can be managed according to the design of device structure. In the “regular” tandem structure (FIG. 2A), the deposition order of interface layer 202 will be electron-IL 204, recom-IL 206, and then hole-IL 208. In the “inverted” (or inverted) tandem structure (FIG. 2B), the deposition order of interface layer 202 will be hole-IL 208, recom-IL 206, and then electron-IL 204.

According to some embodiments, the recom-IL can be ignored (see, e.g., FIGS. 3A and 3B) if either one of hole-IL 208 and electron-IL 204 also serves as a recombination center for charges to recombine. An example of such an embodiment can be found in Demonstration 1, which is discussed in the Examples section below.

According to some embodiments of the current invention, examples of solution-processed inorganic materials for the hole-IL may include, but are not limited to, vanadium oxide (V₂O₅, VO₃, VO_{X}), molybdenum oxide (MoO₃, MoO_{X}), tungsten oxide (WO₃, WO_{X}), copper oxide (CuO, CuO₂, CuO_{X}), nickel oxide (NiO, NiO₂, NiOx), rhenium oxide (ReO₃, Re₂O₇, ReO_{X}), gold nanoparticles (AuNP), platinum nanoparticles (PtNP), silver nanaparticles (AgNPs), and a combination of the above. Metal and metal oxide nanoparticles solution may contain some polymer materials as binders in some embodiments. Examples of the polymers may include, but are not limited to, polyethylene glycol (PEO), polyvinyl alcohol (PVA), polyvinylpyrrolidone (PVP), or other polymers known to those skill in the art or future equivalents thereof. In some embodiments, the metal and metal oxide nanoparticles can also be doped by a p-dopant or n-dopant atom to increase their mobility.

A function of the hole-IL is transporting hole carries while blocking electron carriers. A suitable work function for the hole-IL may range from 4.2 eV to 6.0 eV. The hole-IL can also function as a recombination center.

According to some embodiments of the current invention, examples of solution-processed inorganic nano-materials for the electron-IL may include, but are not limited to, zinc oxide (ZnO, ZnO_{X}), titanium oxide (TiO₂, TiO_{X}), zirconium oxide (ZrO₂, ZrO_{X}), niobium oxide (Nb₂O₅, NbO_{X}), tantalum oxide, (Ta₂O₅, TaO_{X}), silver nanoparticles (AgNP), inorganic carbonate (CsCO₃, CaCO₃, etc) and a combination of the above. Metal and metal oxide nanoparticles solution may contain some polymer materials as binders. Examples of the polymers may include, but are not limited to, polyethylene glycol (PEO), polyvinyl alcohol (PVA), polyvinylpyrrolidone (PVP), or other polymers known to those skill in the art or future equivalents thereof. In some embodiments, the metal and metal oxide nanoparticles can also be doped by a p-dopant or n-dopant atom to increase their mobility.

A function of the electron-IL is transporting electron carries while blocking hole carriers. A suitable work function for electron-IL may range from 2 eV to 4.2 eV. The electron-IL can also function as a recombination center.

According to some embodiments of the current invention, examples of solution-processed inorganic materials as the recomb-IL may include, but are not limited to, zinc oxide (ZnO, ZnO_{X}), titanium oxide (TiO₂, TiO_{X}), silver nanoparticles (AgNP), gold nanoparticles (AuNP), indium tin oxide nanoparticle (ITO NP), Al-doped Zinc oxide nanoparticles (AZO NP), Sb doped tin oxide (ATO NP), graphene, graphene oxide (GO) and a combination of above. Metal and metal oxide nanoparticles solution may contain some polymer materials as binders. Examples of the polymers may include, but are not limited to, polyethylene glycol (PEO), polyvinyl alcohol (PVA), polyvinylpyrrolidone (PVP), or other polymers known to those skill in the art or future equivalents thereof. In some embodiments, the metal and metal oxide nanoparticles can also be doped by a p-dopant or n-dopant atom to increase their mobility.

According to some embodiments of the current invention, examples of non-solution-processed inorganic materials as the recomb-IL may include, but are not limited to, silver thin film by evaporation, gold thin film by evaporation, indium tin oxide thin film by sputtering.

A function of the recom-IL is providing sufficient density of states for charge carriers to recombine. The recomb-IL may also form ohmic contact with both electron-IL and hole-IL. A specific work function is not necessarily required for recomb-IL. However, low resistivity and high doping level may be desired. The recom-IL can sometimes be ignored if either one of the electron-IL or the hole-IL serves as a recombination center for charge carriers to recombine.

The metal oxide and metallic nanoparticle solution can be prepared from precursor, such as alkoxide, acetate, metallic chloride, metallic nitrite, and other polymeric material containing metal and metal oxide as part of its chemical structure. The synthesis of the metal oxide and metal nanoparticle can be obtained from a hydrothermal process and a non-hydrothermal process. The synthesis process may involve, but is not limited to, hydration and condensation of precursor materials.

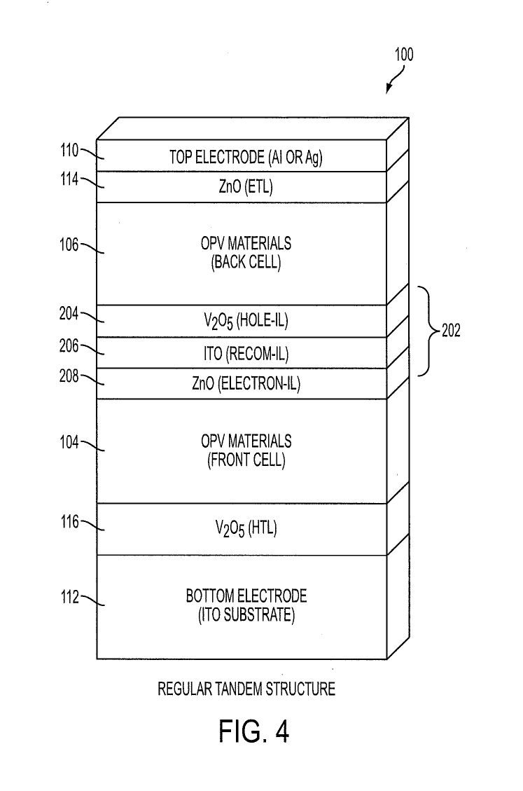

According to some embodiments of the current invention, the processing of a first inorganic hole transporting layer 116 on an ITO substrate 112 may include dissolving metal and metal oxide materials in an organic solvent, such as isopropanol, acetone, ethanol, methanol, butanol, 2-ethoxyethanol, and 2-methoxyethanol, for example, and coating the top of the ITO substrate 112 with the resulting solution. The metal and metal oxide are either dissolved in a one solvent solution, or in a multiple solvents solution. The metal and metal oxide materials can also be processed through solution processes that include, but are not limited to, spin coating, spray coating, slot-die coating, bar coating, screen printing, and doctoral blade coating. For example, V₂O₅ may be deposited from isopropanol solution by spin-coating method according to one embodiment. FIG. 4 shows an example of hole transporting layer (HTL 116) in an organic tandem solar cell according to an embodiment of the current invention.

According to some embodiments, processing of organic materials of the front cell 104 may include dissolving organic materials and acceptor materials in an organic solvent, such as benzene, chlorobenzene, dichlorobenzene, chloroform, THF, toluene, xylene and a combination of the above, and coating the top of the bottom electrode 112 with the resulting solution. In addition to major solvent(s), solvent additives such as OT, DIO, and CN, for example, may also be included in the solvents. The organic materials and acceptor materials are either dissolved in the same solution and coated together, or dissolved in separated solutions and coated sequentially. The organic materials can also be processed through many coating methods that include, but are not limited to, spin coating, spray coating, slot-die coating, bar coating, screen printing, doctoral blade coating, etc. For example, organic materials may deposited from dichlorobenzene solution by spin-coating method according to some embodiments of the current invention. FIG. 4 shows an example of the front cell 104 in a regular tandem structure solar cell 100.

According to some embodiments of the current invention, the processing of electron-IL 208 may include dissolving metal and metal oxide nano-materials in an organic solvent, such as isopropanol, acetone, ethanol, methanol, butanol, 2-ethoxyethanol, and 2-methoxyethanol for example, and coating the resulting solution on top of the organic materials. (See FIG. 4.) The metal and metal oxide solution are either dissolved in a one solvent solution, or dissolved in a multiple solvents solution. The metal and metal oxide materials can also be processed through solution processes that include, but are not limited to, spin coating, spray coating, slot-die coating, bar coating, screen printing, and doctoral blade coating, for example. For example, a ZnO solution may be deposited from a 2-ethoxyethanol solution by a spin-coating method.

According to some embodiments of the current invention, the processing of the recom-IL 206 may include dissolving metal and metal oxide nano-materials in an organic solvent, such as isopropanol, acetone, ethanol, methanol, butanol, 2-ethoxyethanol, 2-methoxyethanol, for example, and then coating the resulting solution on top of the organic materials. (See FIG. 4.) The metal and metal oxide are either dissolved in a one solvent solution, or dissolved in a multiple solvents solution. The metal and metal oxide materials can also be processed through solution processes that include, but are not limited to, spin coating, spray coating, slot-die coating, bar coating, screen printing, and doctoral blade coating. For example, ITO nanoparticle may be deposited from an isopropanol and water mixture solution by spin-coating method, according to an embodiment of the current invention.

According to some embodiments of the current invention, the processing of the hole-IL 204 may include dissolving metal and metal oxide nano-materials in an organic solvent, such as isopropanol, acetone, ethanol, methanol, butanol, 2-ethoxyethanol, and 2-methoxyethanol, for example, and coating the resulting solution on top of the organic materials. (See FIG. 4.) The metal and metal oxide are either dissolved in a one solvent solution, or dissolved in a multiple solvents solution. The metal and metal oxide materials can also be processed through solution processes that include, but are not limited to, spin coating, spray coating, slot-die coating, bar coating, screen printing, and doctoral blade coating. For example, V₂O₅ may be deposited from an isopropanol solution by spin-coating method according to an embodiment of the current invention.

According to some embodiments of the current invention, one or more polymers, crosslinkers, adhesion promoters, thickeners, and other processing additives can be incorporated into the metal and metal oxide solution formulation. In this way, a robust and solvent-resistive interconnecting layer 202 may be formed to prevent re-dissolving the front cell 104 while sequentially depositing the back cell 106 using the same organic solvent. For example, PEG polymer may be added into a ZnO solution, PVA polymer may be added into ITO nanoparticle, and perfluorinated polymer Nafion® may be added to V₂O₅ solution.

According to some embodiments of the current invention, the processing of organic materials of the back cell 106 may include dissolving organic materials and acceptor materials in an organic solvent, such as benzene, chlorobenzene, dichlorobenzene, chloroform, THF, toluene, xylene and a combination of the above, and the resulting solution may be coated on top of the bottom electrode 112, or on top of those layers that are on top of the bottom electrode 112. (See FIG. 4.) In addition to major solvent(s), solvent additives such as OT, DIO, and CN may also be included in the solvents. The organic materials and acceptor materials are either dissolved in the same solution and coated together, or dissolved in a separated solution and coated sequentially. The organic materials can also be processed through many coating methods that include, but are not limited to, spin coating, spray coating, slot-die coating, bar coating, screen printing, and doctoral blade coating. For example, organic materials may be deposited from a dichlorobenzene solution by a spin-coating method according to an embodiment of the current invention.

According to some embodiments of the current invention, the processing of a last inorganic electron transporting layer (ETL) 114 on ITO substrate 112 may include dissolving metal and metal oxide materials in an organic solvent, such as isopropanol, acetone, ethanol, methanol, butanol, 2-ethoxyethanol, and 2-methoxyethanol, for example, and coating the resulting solution on top of the ITO substrate 112, or the layers disposed on top of the ITO substrate 112. (See FIG. 4.) The metal and metal oxide solution may either be dissolved in a one solvent solution, or dissolved in a multiple solvents solution. The metal and metal oxide materials can also be processed through solution processes that include, but are not limited to, spin coating, spray coating, slot-die coating, bar coating, screen printing, and doctoral blade coating. For example, ZnO may be deposited from 2-ethoxyethanol solution by a spin-coating method according to one embodiment of the current invention.

Two kinds of electrodes may be used in embodiments of the current invention: transparent and reflective electrodes. The reflective electrode can be processed through a vacuum method such as, thermal evaporation and sputtering, for example, and solution processes that include, but are not limited to, silver paste, and silver paint. According to some embodiments, transparent electrodes can be deposited from a silver nanowire solution. The silver nanowire solution can be processed from isopropanol, acetone, ethanol, methanol, butanol, 2-ethoxyethanol, and 2-methoxyethanol, and coated on top of the solar cell by spin coating, spray coating, slot-die coating, bar coating, screen printing, and doctoral blade coating, for example. An organic tandem solar cell using a transparent top electrode made of silver nanowire can be a visibly semitransparent organic tandem solar cell.

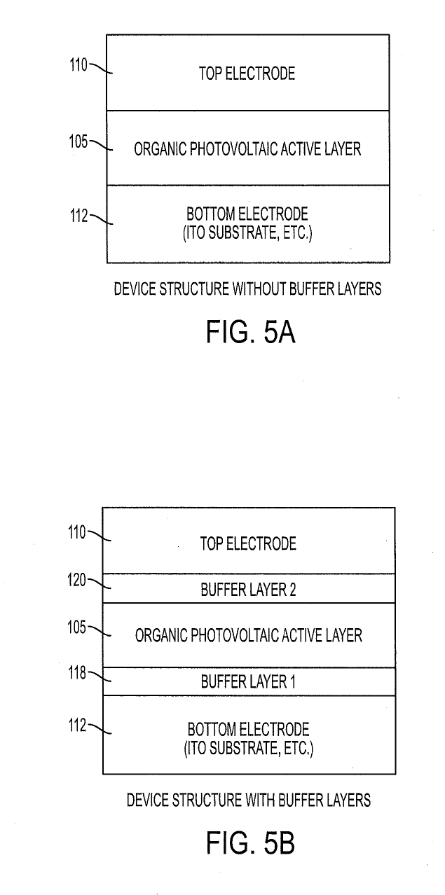

As seen in FIGS. 3A-4, for example, there are two electrodes 110, 112 on the top and bottom sides of the visibly semitransparent organic tandem solar cell 100 to collect electricity. FIG. 5A shows a simplified example of such a two-electrode arrangement. To improve the contact between the electrodes 110, 112 and organic active layers (shown as 105 in FIG. 5A), electrical buffer layers 118, 120 may be applied in between each electrode and the organic active layer, as shown in FIG. 5B. The electrical buffer layers not only improve the electrical contact between layers, but also act as protecting films for sublayer protection, thus preventing damage to the organic materials during the process of depositing the top electrode 110.

According to some embodiments of the current invention, electrical buffer layers may be applied above the organic materials, below the organic materials, or both. Buffer layer materials may include metal oxides (examples include, but are not limited to, ZnO, TiO₂, MoO₃, V₂O₅, NiO, and WO₃), aqueous polymers (examples include, but are not limited to, PEO, PEDOT:PSS, PANI, PANI:PSS, polypyrrole, and conjugated polyelectrolyte) and salts (examples include, but are not limited to CsF, LiF, and Cs2CO₃)

The OPV tandem devices utilizing the facile solution-processed top electrodes according to some embodiments of the current invention can be integrated into buildings, portable electronics, etc. For example, application areas include building roof tops or windows, car windows, liquid crystal displays, light-emitting diodes, and electrochromic devices. However, applications are not limited to those listed here. Integrated devices such as those of the above-listed application can be used to harvest the ambient light or sunlight energy or the backlight energy liquid crystal display. In other words, the applications are wide-ranging and can enable significant energy production previously unrealized in some of these applications.

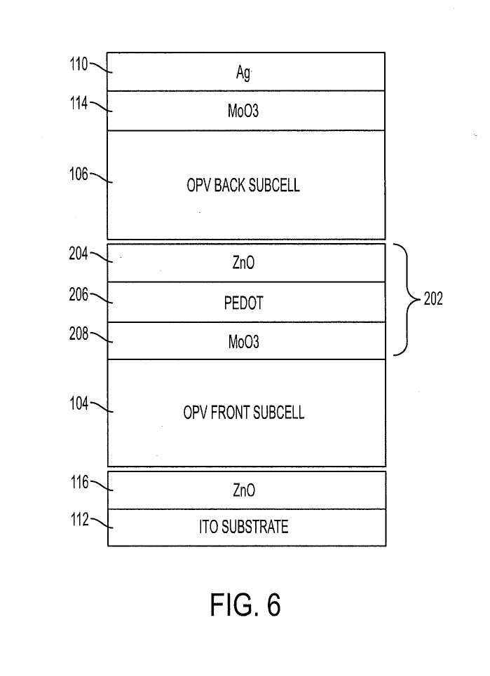

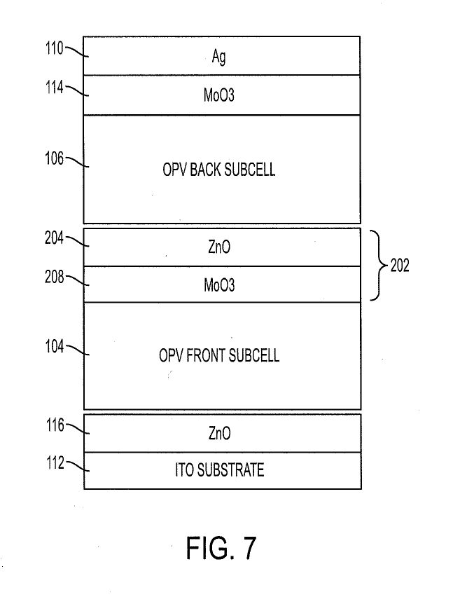

According to some embodiments of the current invention, an inverted tandem structure is provided. The inverted tandem structure may have an inorganic or a hybrid interconnecting layer (ICL) 202. FIG. 6 shows an example of an inverted tandem structure according to an embodiment of the current invention. The interconnecting layers can be an all metal oxide base (MoO3/ZnO) or a metal oxide polymer hybrid (e.g., MoO3/PEDOT:PSS/ZnO). A hole transporting layer 114 is formed of MoO3 in FIG. 6, but can be replaced by other solution processed inorganic materials, including but not limited to V2O5, WO3, NiO, CuO or a combination of these oxides, and may be a doped form of these metal oxides. The electron transporting layer 116 is formed of ZnO in FIG. 6, but can be replaced by other solution processed inorganic materials, including but not limited to TiO2, NbO, CuO2 or a combination of these oxides, and may be a doped form of these metal oxides. A recombination layer 206 can be formed of PEDOT:PSS or can be replaced by other solution processed inorganic materials, including but not limited to ITO NP, metal nanoparticles (Au, Ag, and Al, Sn NP) or a combination of these oxides, and can be a doped form of these metal oxides. As discussed above, the recombination layer 206 can alternatively be removed from the design to reduce the complication of the device structure, as shown in FIG. 7.

The absorbing materials in the subcells 104, 106 can be either identical or non-identical. Identical absorbing materials form so called homojunction subcells. Non-identical absorbing materials form so called heterojunction subcells. The tandem structure according to embodiments of the current invention can use either homojunction or heterojunction subcells.

### EXAMPLES

The following examples of the “regular structure” OPV tandem device use the solution-processed metal and metal oxide interconnecting layer.

### Example 1

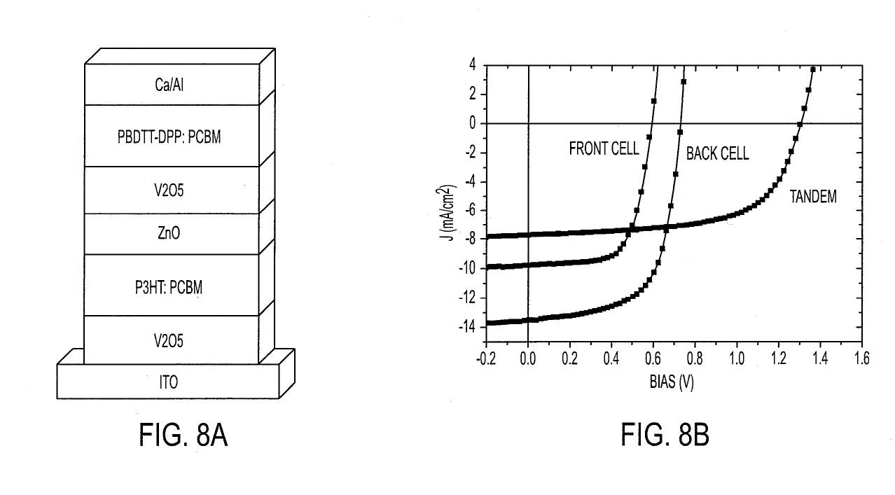

This example describes the creation and performance of a regular tandem device using an inorganic interconnecting layer without a recom-IL according to an embodiment of the current invention. A schematic of the device of this example is shown in FIG. 8A. Large bandgap polymer P3HT and PC₆₀BM are blended in dichlorobenzene solution and spin coated onto ITO glass which has been pre-coated with V₂O₅ as an anode electrical buffer layer. ZnO sol gel solution in (1:1 2-ethoxyethanol and ethanol mixture solvent) is deposited on top of organic layer to form a 30˜50 nm thick electron-IL. The V₂O₅ sol gel solution adding a small amount of Nafion® polymer is coated on top of ZnO layer to form the hole-IL. Low bandgap polymer PBDTT-DPP and PC₇₀BM are blended in dichlorobenzene solution and spin coated onto V₂O₅ layer. 20 nm of calcium (Ca) and 100 nm of aluminum (Al) are deposited sequentially by thermal evaporation. The power conversion efficiency of the organic tandem solar cell of this example is 6.22%. FIG. 8B and Table 1 show the performance of the device depicted in FIG. 8A.

TABLE 1
Performance of the device of Example 1.

| Sample | Voc | Jsc | Eff | FF |
|---|---|---|---|---|
| (Electrode Choice) | (V) | (mA cm⁻²) | (%) | (%) |
| Front Cell (P3HT:PCBM) | 0.59 | 9.76 | 3.82 | 66.6 |
| Back Cell (PBDTT-DPP:PCBM) | 0.72 | 13.51 | 6.25 | 63.9 |
| Tandem Cell | 1.30 | 7.71 | 6.22 | 62.0 |

### Example 2

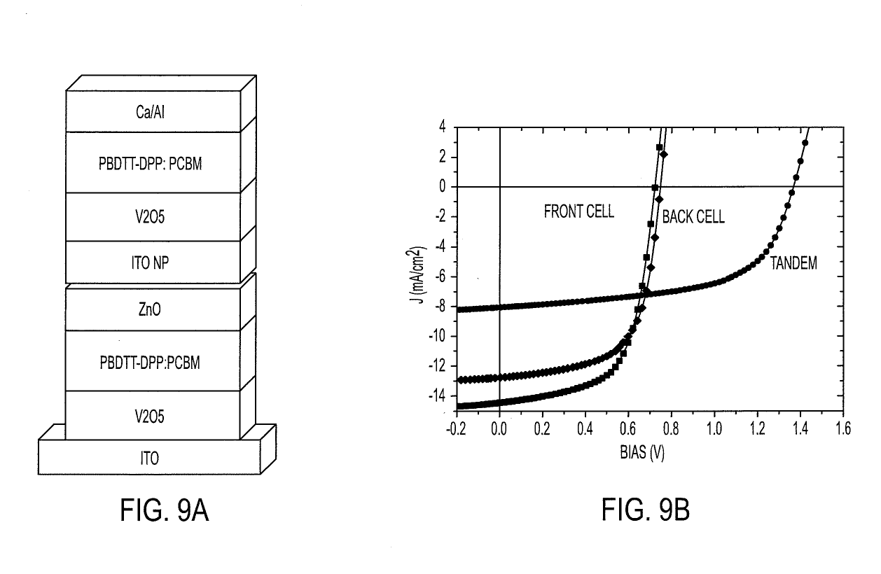

This example describes the creation and performance of a regular tandem device using an inorganic interconnecting layer with recom-IL according to an embodiment of the current invention. A schematic of this device is shown in FIG. 9A. Low bandgap polymer PBDTT-DPP and PC₆₀BM are blended in dichlorobenzene solution and spin coated onto ITO glass which has been pre-coated with V₂O₅ as an anode electrical buffer layer. ZnO sol gel solution in (1:1 2-ethoxyethanol and ethanol mixture solvent) is deposited on top of an organic layer to form a 30˜50 nm thick electron-IL. The ITO nanoparticle solution in isopropanol solvent (obtained from Sigma-Alrich) is coated on top of ZnO layer as a recom-IL. The V₂O₅ sol gel solution adding a small amount of Nafion® polymer is coated on top of ITO nanoparticle layer to form a hole-IL. Low bandgap polymer PBDTT-DPP and PC₇₀BM are blended in dichlorobenzene solution and spin coated onto V₂O₅ layer. 20 nm of calcium (Ca) and 100 nm of aluminum (Al) are deposited sequentially by thermal evaporation. The power conversion efficiency of the organic tandem solar cell of this example is 6.52%. FIG. 9B and Table 2 show the performance of the device depicted in FIG. 9A.

TABLE 2
Performance of the device of Example 2.

| Sample | Voc | Jsc | Eff | FF |
|---|---|---|---|---|
| (Electrode Choice) | (V) | (mA cm⁻²) | (%) | (%) |
| FrontCell(PBDTT-DPP:PC₆₀BM) | 0.74 | 12.7 | 6.06 | 64.0 |
| Back Cell (PBDTT-DPP:PC₇₀BM) | 0.72 | 14.4 | 6.55 | 63.1 |
| Tandem Cell | 1.368 | 8.04 | 6.52 | 59.34 |

### Example 3

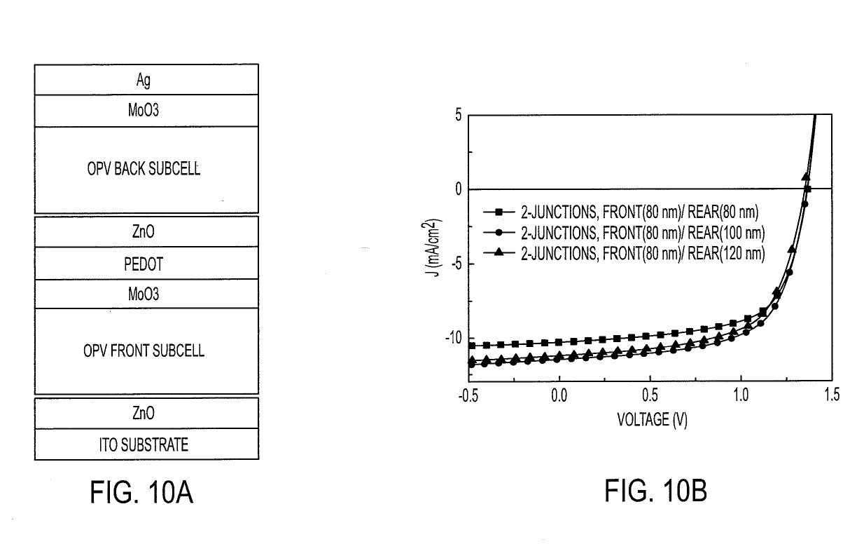

This example deals with the creation and performance of an inverted tandem using a hybrid interconnecting layer with PEDOT:PSS. FIG. 10A shows a schematic of the device of this example. Low bandgap polymer PDTP-DFBT and PC₇₁BM are blended in dichlorobenzene solution and spin coated onto ITO glass which has been pre-coated with ZnO as anode electrical buffer layer. MoO3 is deposited on top of an organic layer to form a 30˜50 nm thick hole-IL. The PEDOT:PSS solution from isoprop solvent (obtained from Sigma-Alrich) is coated on top of an MoO3 layer as a recom-IL. The ZnO sol gel solution is coated on top of PEDOT:PSS layer to form an electron-IL. Low bandgap polymer PDTP-DFBT and PC₇₁BM are blended in dichlorobenzene solution and spin coated onto a ZnO layer. 100 nm of silver (Ag) are deposited by thermal evaporation. The power conversion efficiency of the organic tandem solar cell of this example is 9.6%. FIG. 10B and Table 3 show the performance of the device of depicted in FIG. 10A.

TABLE 3
Performance of the device of Example 2.

| Active layer thick- | Voc | Jsc | FF | PCE |
|---|---|---|---|---|
| ness_{Front/Rear} (nm) | (V) | (mA/cm²) | (%) | (%) |
| 80/80 | 1.36 | 10.4 | 66 | 9.3 |
| 80/100 | 1.36 | 11.5 | 65 | 10.2 |
| 80/120 | 1.35 | 11.2 | 63 | 9.6 |

### Example 4

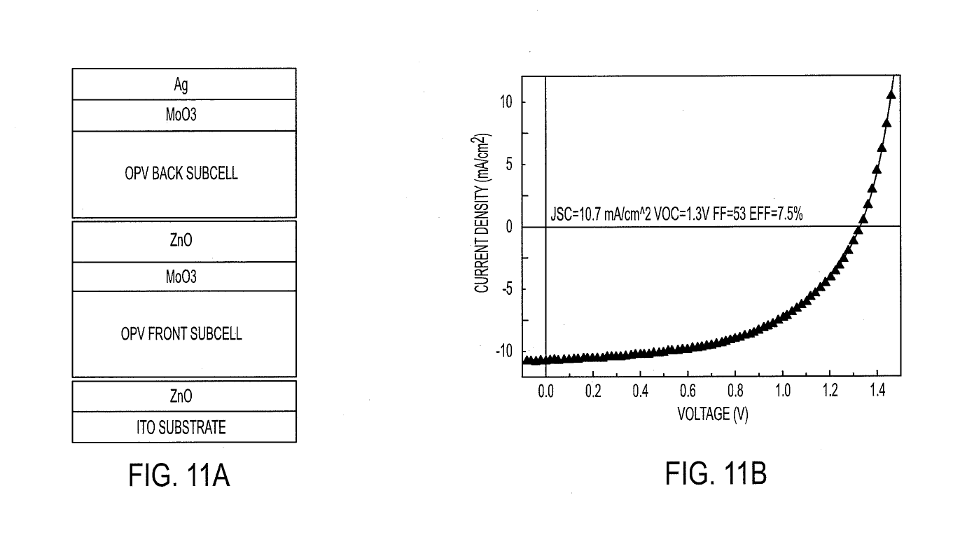

This example deals with the creation and performance of an inverted tandem using an inorganic interconnecting layer. FIG. 11A shows a schematic of the device of this example. Low bandgap polymer PDTP-DFBT and PC₇₁BM are blended in dichlorobenzene solution and spin coated onto ITO glass which has been pre-coated with ZnO as an anode electrical buffer layer. MoO3 is deposited on top of an organic layer to form a 30˜50 nm thick hole-IL. The ZnO sol gel solution is coated on top of a MoO3 layer to form an electron-IL. Low bandgap polymer PDTP-DFBT and PC₇₁BM are blended in dichlorobenzene solution and spin coated onto a ZnO layer. 00 nm of silver (Ag) are deposited by thermal evaporation. The power conversion efficiency of the organic tandem solar cell of this example is 7.5%. FIG. 11B shows the performance.

### Example 5

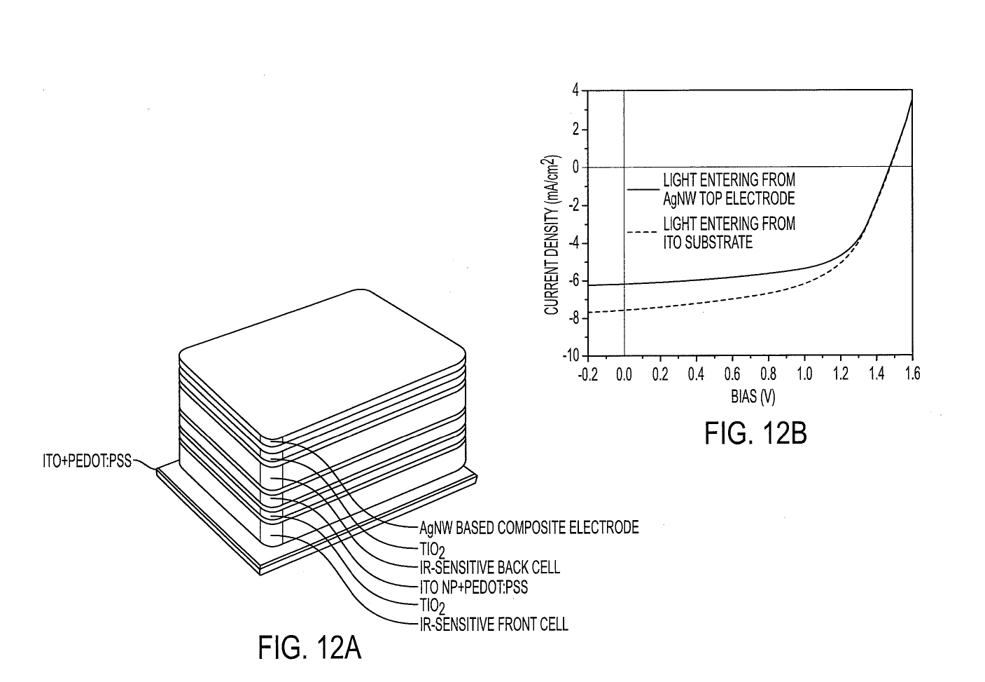

This example deals with the creation and performance of a transparent tandem using a hybrid interconnecting layer with PEDOT:PSS. FIG. 12A shows a schematic of the device of this example Low bandgap polymer PBDTT-DPP and PC₆₀BM are blended in dichlorobenzene solution and spin coated onto ITO glass which has been pre-coated with V₂O₅ as an anode electrical buffer layer. TiO2 sol gel solution in (1:1 2-ethoxyethanol and ethanol mixture solvent) is deposited on top of an organic layer to form a 30˜50 nm thick electron-IL. The ITO nanoparticle solution in isopropanol solvent (obtained from Sigma-Alrich) is coated on top of a TiO2 layer as a recom-IL. PEDOT:PSS is coated on top of an ITO nanoparticle layer to form a hole-IL. Low bandgap polymer PBDTT-DPP and PC₆₀BM are blended in dichlorobenzene solution and spin coated onto PEDOT:PSS layer. The 400 nm silver nanowire composite electrode is deposited by spray-coating. The power conversion efficiency of the organic tandem solar cell is 6.2%, FIG. 12B and Table shows the device structure and the device performance.

TABLE 4
Performance of the device of example 5.

| | V_{oc} | J_{sc} | FF | PCE |
|---|---|---|---|---|
| | (V) | (mA/cm²) | (%) | (%) |
| Front subcell | 0.76 | 9.11 | 61.2 | 4.27 |
| Back subcell | 0.73 | 10.9 | 58.1 | 4.60 |
| Tandem | 1.47 | 7.38 | 56.9 | 6.19 |

In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

We claim:

1. An organic tandem photovoltaic device, comprising:
a first electrode;
a second electrode spaced apart from said first electrode;
first and second photoactive organic bulk heterojunction layers; and
an interconnecting layer between and electrically connecting said first and second photoactive organic bulk heterojunction layers,
wherein said interconnecting layer comprises an electron extracting interface layer of a first inorganic material and a hole extracting interface layer of a second inorganic material.

2. The organic tandem photovoltaic device according to 1, wherein said interconnecting layer further comprises a recombination layer of a third material.

3. The organic tandem photovoltaic device according to 2, wherein said third material comprises indium-tin-oxide nanoparticles.

4. The organic tandem photovoltaic device according to 1, wherein said first inorganic material comprises zinc oxide nanoparticles and said second inorganic material comprises vanadium oxide nanoparticles.

5. The organic tandem photovoltaic device according to 1, wherein said first inorganic material comprises zinc oxide nanoparticles and said second inorganic material comprises molybdenum trioxide.

6. The organic tandem photovoltaic device according to claim 1, further comprising a hole transporting layer and an electron transporting layer,
wherein said first photoactive organic bulk heterojunction layer is disposed between said hole extracting interface layer and said electron transporting layer, and
wherein said second photoactive organic bulk heterojunction layer is disposed between said electron extracting interface layer and said hole transporting layer.

7. The organic tandem photovoltaic device according to claim 6, wherein said hole transporting layer comprises vanadium oxide.

8. The organic tandem photovoltaic device according to claim 6, wherein said hole transporting layer comprises molybdenum trioxide.

9. The organic tandem photovoltaic device according to claim 6, wherein said electron transporting layer comprises zinc oxide.

10. The organic tandem photovoltaic device according to claim 1, wherein the interconnecting layer comprises a metal oxide polymer hybrid.

11. A method of manufacturing an organic tandem photovoltaic cell, comprising:
applying a first organic photovoltaic cell material via solution processing onto a substrate;
applying an electron extracting interface layer via solution processing on top of said first organic photovoltaic cell material;
applying a hole extracting interface layer via solution processing on top of said electron extracting interface layer; and
applying a second organic photovoltaic cell material via solution processing on top of said electron extracting interface layer.

12. The method of manufacturing of claim 11, further comprising applying a recombination interface layer via solution processing on top of said electron extracting interface layer before applying said hole extracting interface layer.

13. A method of manufacturing an organic, inverted tandem photovoltaic cell, comprising:
applying a first organic photovoltaic cell material via solution processing onto a substrate;
applying a hole extracting interface layer via solution processing on top of said first organic photovoltaic cell material;
applying an electron extracting interface layer via solution processing on top of said hole extracting interface layer; and
applying a second organic photovoltaic cell material via solution processing on top of said electron extracting interface layer.

14. The method of manufacturing of claim 13, further comprising applying a recombination interface layer via solution processing on top of said hole extracting interface layer before applying said electron extracting interface layer.
